(19) United States
(12) Patent Application Publication
(10) Pub. No.: US 2015/0171229 A1
(43) Pub. Date: Jun. 18, 2015

(54) SOLAR CELL APPARATUS AND METHOD OF FABRICATING THE SAME

(71) Applicant: LG INNOTEK CO., LTD., Seoul (KR)

(72) Inventor: Jung Hwan Gho, Seoul (KR)

(73) Assignee: LG INNOTEK CO., LTD., Seoul (KR)

(21) Appl. No.: 14/401,528

(22) PCT Filed: Jul. 30, 2013
(86) PCT No.: PCT/KR2013/006851

§ 371 Date: Nov. 16, 2014

(30) Foreign Application Priority Data
Jul. 31, 2012 (KR) 10-2012-0083594

(51) Int. Cl. H01L 31/02; H01L 31/0224

(52) U.S. Cl. CPC H01L 31/02008; H01L 31/022441

(57) ABSTRACT

A solar cell apparatus includes a support substrate, a back electrode layer on the support substrate, a light absorbing layer on the back electrode layer, a buffer layer on the light absorbing layer, a front electrode layer on the buffer layer, a first through hole in the back electrode layer to expose a top surface of the support substrate, and a second through hole through the light absorbing layer and the buffer layer, and overlapped with a portion of the first through hole. A method of fabricating the solar cell apparatus includes forming a back electrode layer on a support substrate, forming a first through hole, forming a light absorbing layer on the back electrode layer, forming a second through hole, and forming a front electrode layer on the light absorbing layer and in the second through hole overlapped with a portion of the first through hole.

### TECHNICAL FIELD

The embodiment relates to a solar cell apparatus and a method of fabricating the same.

### BACKGROUND ART

Recently, as energy consumption is increased, a solar cell has been developed to convert solar energy into electrical energy.

In particular, a CIGS-based solar cell, which is a P-N hetero junction apparatus having a substrate structure including a glass substrate, a metallic back electrode layer, a P type CIGS-based light absorbing layer, a high resistance buffer layer, and an N type window layer, has been extensively used.

The solar cell is provided therein with a first through hole, a second through hole, and a third through hole, and a dead zone is formed by the second and third through holes. The dead zone serves as a cause to reduce the efficiency of the solar cell.

### DISCLOSURE OF INVENTION

### Technical Problem

The embodiment provides a solar cell apparatus capable of preventing a short phenomenon and representing improved performance and a method of fabricating the same.

### Solution to Problem

According to the embodiment, there is provided a solar cell apparatus including a support substrate, a back electrode layer on the support substrate, a light absorbing layer on the back electrode layer, a buffer layer on the light absorbing layer, a front electrode layer on the buffer layer, a first through hole in the back electrode layer to expose a top surface of the support substrate, and a second through hole formed through the light absorbing layer and the buffer layer. The second through hole is overlapped with a portion of the first through hole.

According to the embodiment, there is provided a method of fabricating a solar cell apparatus. The method includes forming a back electrode layer on a support substrate, forming a first through hole to expose a top surface of the support substrate to the back electrode layer, forming a light absorbing layer on the back electrode layer, forming a second through hole to expose a top surface of the back electrode layer and the support substrate to the light absorbing layer, and forming a front electrode layer on the light absorbing layer and in the second through hole. The second through hole is overlapped with a portion of the first through hole.

### Advantageous Effects of Invention

As described above, according to the solar cell apparatus of the embodiment, the second through hole has an inner lateral side inclined in the overhang structure in the light absorbing layer. Accordingly, when the front electrode layer is formed, the front electrode layer can be naturally patterned by the second through hole.

Therefore, according to the solar cell apparatus of the embodiment, even though the third through hole is not additionally formed, the front electrode layer is patterned to form a plurality of front electrodes. Therefore, the solar cell apparatus of the embodiment can be easily fabricated.

In addition, the first through hole is overlapped with the second through hole, and the connection part is provided in the overlap portion, so that the see-through module can be realized without the loss in the solar cell efficiency.

In addition, when the third through hole is not formed, the solar cell apparatus according to the embodiment may have an effective power generation region with a wide area. In other words, the effective power generation region may be provided after the second through hole has been formed. Therefore, according to the solar cell apparatus of the embodiment, a dead zone can be reduced, and the improved photo-electric conversion efficiency can be represented.

### BRIEF DESCRIPTION OF DRAWINGS

FIG. 1 is a section view showing a solar cell panel according to the embodiment.

FIGS. 2 to 5 are sectional views showing a method of fabricating a solar cell panel according to the embodiment.

### MODE FOR THE INVENTION

In the following description of the embodiments, it will be understood that, when a layer (film), a region, a pattern or a structure is referred to as being “on” or “under” another substrate, layer (film), region, pad or pattern, it can be “directly” or “indirectly” on the other substrate, layer (film), region, pad, or pattern, or one or more intervening layers may also be present. Such a position of each layer will be described with reference to the drawings.

The thickness and size of each layer (film), region, pattern or structure shown in the drawings may be modified for the purpose of convenience or clarity. In addition, the size of each layer (film), region, pattern or structure does not utterly reflect an actual size.

Hereinafter, the embodiment will be described with reference to accompanying drawings.

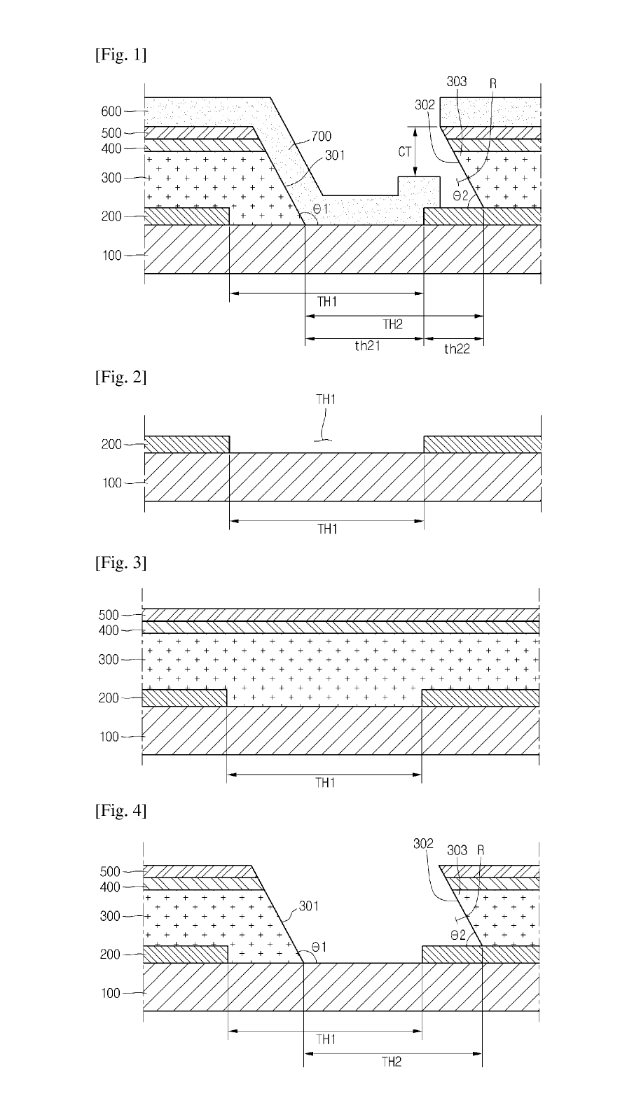

Hereinafter, a solar cell apparatus according to the embodiment will be described in detail with reference to FIG. 1. FIG. 1 is one sectional view showing a solar cell panel according to the embodiment.

Referring to FIG. 1, the solar cell panel according to the embodiment includes a support substrate 100, a back electrode layer 200, a light absorbing layer 300, a buffer layer 400, a high resistance buffer layer 500, a front electrode layer 600, and a plurality of connections 700.

The support substrate 100 may include an insulator. The support substrate 100 may include a glass substrate, a plastic substrate, or a metallic substrate. In more detail, the support substrate 100 may include a soda lime glass substrate. The support substrate 100 may be transparent. The support substrate 100 may be rigid or flexible.

The back electrode layer 200 is provided on the support substrate 100. The back electrode layer 200 is a conductive layer, and the back electrode layer 200 may include one of molybdenum (Mo).

In addition, the back electrode layer 200 may include at least two layers. In this case, the layers may include the same metal or different metals.

First through holes TH1 are formed in the back electrode layer 200. The first through holes TH1 are open regions to expose the top surface of the support substrate 100. When viewed in a plan view, the first through holes TH1 may have the shape extending in the first direction.

The back electrode layer 200 is divided into a plurality of back electrodes by the first through holes TH1. In other words, the back electrodes are defined by the first through holes TH1.

The back electrodes are spaced apart from each other by the first through holes TH1. The back electrodes are arranged in the form of a stripe.

Alternatively, the back electrodes may be arranged in the form of a matrix. In this case, the first through holes TH1 may be provided in the form of a lattice when viewed in a plan view.

The first through holes TH1 is provided therein with the light absorbing layer 300 and the connection part 700.

The transparent connection part 700 is provided in the first through holes TH1, thereby realizing a see-through module.

Each first through hole TH1 may have a width in the range of about 50 μm to about 900 μm. If the width of the first through hole TH1 is less than 50 μm, the see-through effect may be rapidly degraded.

The light absorbing layer 300 is provided on the back electrode layer 200. The light absorbing layer 300 is provided at a portion of the first through holes TH1.

The light absorbing layer 300 may include a group I-III-VI-based compound. For example, the light absorbing layer 300 may have a Cu(In,Ga)Se2(CIGS) crystal structure, a Cu(In)Se2 crystal structure, or a Cu(Ga)Se2 crystal structure.

The energy band gap of the light absorbing layer 300 may be in the range of about 1 eV to 1.8 eV.

The buffer layer 400 is provided on the light absorbing layer 300. The buffer layer 400 includes cadmium sulfide (CdS), and the energy bandgap of the buffer layer 400 is in the range of about 2.2 eV to about 2.4 eV.

The high resistance buffer layer 500 may be further provided on the buffer layer 400.

The high resistance buffer layer 500 includes i-ZnO which is not doped with impurities. The energy bandgap of the high resistance buffer layer 500 may be in the range of about 3.1 eV to about 3.3 eV.

The second through holes TH2 are formed through the light absorbing layer 300, the buffer layer 400, and the high resistance buffer layer 500. The second through holes TH2 are formed through the light absorbing layer 300. In addition, the second through holes TH2 are open regions to expose the top surfaces of the support substrate 100 and the back electrode layer 200.

The second through holes TH2 are overlapped with a portion of the first through holes TH1. A portion of the second through holes TH2 is formed above the first through holes TH1.

The second through holes TH2 have a shape extending in the first direction.

The second through holes TH2 may be in the range of about 5 μm to about 900 μm. If the width of the second through hole TH2 is less than 5 μm, the second through hole TH2 may not be realized.

In addition, a plurality of light absorbing parts are defined in the light absorbing layer 300 by the second through holes TH2. In other words, the light absorbing layer 300 is divided into the light absorbing parts by the second through holes TH2.

In detail, each second through hole TH2 includes a first part th21 and a second th22.

The first part th21 exposes the top surface of the support substrate 100. The first part th21 is overlapped with a portion of the first through hole TH1. The connection part 700 is provided in the first part th21, and the see-through module may be realized through the first part th21. In other words, the first part th21 is overlapped with the first through hole TH1, so that the see-through module can be realized without the loss in the solar cell efficiency.

The see-through module may be realized by widening the width of the first through hole TH1 and maintaining the width of an existing cell. Alternatively, the first through hole TH1 may be realized by maintaining the width of the first through hole TH1 to an existing width, and increasing the number of cells to widen the see-through region. In other words, the number of the transmitted regions may be increased by increasing the number of cells so that the back side of the solar cell module may be much more seen.

The second part th22 exposes the top surface of the back electrode layer 200.

The second through holes TH2 may be inclined with respect to the support substrate 100 or the back electrode layer 200. In other words, the second through holes TH2 include a first inner lateral side 301 and a second inner lateral side 302, that face each other, and the first inner lateral side 301 may be inclined with respect to the support substrate 100. The second inner lateral side 302 may be inclined with respect to the back electrode layer 200.

In detail, the first part th21 includes the first inner lateral side 301. The first inner lateral side 301 may be inclined in an over-hang structure with respect to the top surface of the support substrate 100. In other words, the first inner lateral side 301 may be inclined outward of each second through hole TH2. Accordingly, an angle θ1 of the first inner lateral side 301 extending outward of each through hole TH2 about the top surface of the support substrate 100 may be greater than 90°.

The second part th22 includes the second inner lateral side 302. The second inner lateral side 302 faces the first inner lateral side 301. The second inner lateral side 302 may be substantially parallel to the first inner lateral side 301. The second inner lateral side 302 is inclined with respect to the top surface of the back electrode layer 200.

The second inner lateral side 302 may be inclined inward of the second through hole TH2. Accordingly, an angle of the second inner lateral side 302 extending inward of the second through hole TH2 about the top surface of the back electrode layer 200 may be smaller than 90°. In more detail, the angle θ2 of the second inner lateral side 301 extending inward of each second through hole TH2 about the top surface of the back electrode layer 200 may be in the range of about 30° to about 60°. If the angle θ2 of the second inner lateral side 301 extending inward of each second through hole TH2 about the top surface of the back electrode layer 200 is smaller than 30°, the structure of the solar cell may be destructed. If the angle θ2 of the second inner lateral side 301 extending inward of each second through hole TH2 about the top surface of the back electrode layer 200 is larger than 60°, an electrical short phenomenon may occur.

Accordingly, the protrusion 303 and a recess R are formed in the second through hole TH2. The protrusion 303 protrudes inward of the second through hole TH2. In addition, the recess R is formed under the protrusion 303. In other words, the recess R is a space between the protrusion 303 and the back electrode layer 200. Accordingly, the protrusion 303 is spaced apart from the back electrode layer 200 by the recess R. The protrusion 303 and the recess R are inevitably formed since the second lateral side 302 is inclined in the overhang structure.

The protrusion 303 protrudes in a side direction from one lateral side of the light absorbing part. In more detail, the protrusion 303 protrudes in the side direction from the upper lateral side of the light absorbing part. In addition, the protrusion 303 may be integrally formed with each light absorbing part.

A plurality of buffers are defined in the buffer layer 400 by the second through holes TH2. In other words, the buffer layer 400 is divided into the buffers by the second through holes TH2.

A plurality of high resistance buffers are defined in the high resistance buffer layer 500 by the second through holes TH2. In other words, the high resistance buffer layer 500 is divided into the high resistance buffers by the second through holes TH2.

The front electrode layer 600 is provided under the high resistance buffer layer 500. The front electrode layer 600 is transparent and serves as a conductive layer. In addition, the resistance of the front electrode layer 600 is higher than that of the back electrode layer 200.

The front electrode layer 600 includes an oxide. For example, the front electrode layer 600 includes an Al doped zinc oxide (AZO) or Ga doped zinc oxide (GZO).

The thickness of the front electrode layer 600 may be in the range of about 0.5 μm to about 1.5 μm. The front electrode layer 600 may be naturally patterned by the second through holes TH2. Since the second inner lateral side 302 has the overhang structure, a material constituting the front electrode layer 600 may not be deposited on the second inner lateral side 302.

Accordingly, a disconnection region CT is defined in the front electrode layer 600 to expose a portion or an entire portion of the second inner lateral side 302. Accordingly, the front electrode layer 600 may be divided into a plurality of front electrodes by the second through holes TH2.

The front electrodes have shapes corresponding to those of the back electrodes. In other words, the front electrodes are arranged in the shape of a stripe. Alternatively, the front electrodes may be arranged in the shape of a matrix.

In addition, a plurality of cells are defined by the second through holes TH2. In other words, the solar cell apparatus according to the embodiment is divided into the cells by the second through holes TH2. In addition, the cells are connected to each other in a second direction crossing a first direction. In other words, current may flow through the cells in the second direction.

The connection parts 700 are provided inside the second through holes TH2. Each connection part 700 extends downward from the front electrode layer 600 to be connected to the back electrode layer 200. For example, each connection part 700 extends from the front electrode of the first cell to be connected to the back electrode of the second cell.

Therefore, the connection part 700 connects adjacent cells to each other. In more detail, the connection part 700 connects front and back electrodes included in the adjacent cells, respectively.

The connection part 700 is integrally formed with the front electrode layer 600. In other words, the connection part 700 includes the same material as that constituting the front electrode layer 600.

An end of the connection part 700 is provided toward the recess R. In detail, the connection part 700 may cover the whole bottom surface of the first part th21 and a portion of the bottom surface of the second part th22. In other words, the connection part 700 may cover the whole bottom surface of the first part th21, and may cover a portion of the bottom surface of the second part th22.

The end of the connection part 700 may be provided in the recess R. The end of the connection part 700 may be spaced apart from the second inner lateral side 302.

As described above, the front electrode layer 600 may be naturally patterned by the second through hoels TH2. Accordingly, in the solar cell panel according to the example embodiment, the front electrode layer 600 may be patterned even though through holes are not additionally formed in addition to the first and second through holes TH1 and TH2. Accordingly, a solar cell panel according to the embodiment can be easily fabricated.

In addition, since additional through holes are not formed, the solar cell panel according to the embodiment may have an active power generation region having a wide area. In other words, the active power generation region may be provided after the second through holes TH2. Accordingly, in the solar cell panel according to the embodiment, the dead zone can be reduced, and the photoelectric conversion efficiency can be improved.

In addition, a portion of each second through hole TH2 is overlapped with each first through hole TH1, so that the see-through module can be realized without loss in the solar cell efficiency. In other words, since the connection part 700 provided in a region in which the first through hole TH1 is overlapped with the second through hole TH2 is transparent, the see-through structure can be formed.

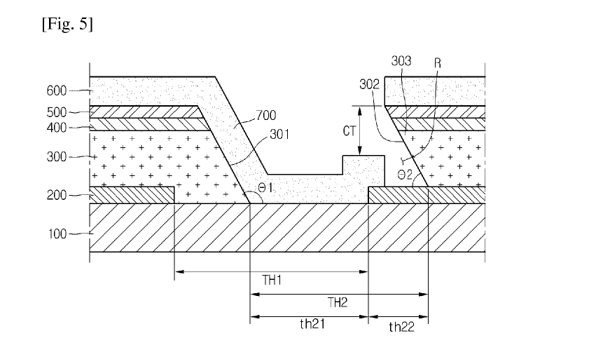

Hereinafter, a method of fabricating the solar cell apparatus of the embodiment will be described with reference to FIGS. 2 to 5. FIGS. 2 to 5 are sectional views showing the fabrication procedure of the solar cell panel according to the embodiment. The present fabricating method will be described by making reference to the above description of the solar cell panel. The above description of the solar cell may be incorporated in the description of the present fabricating method.

Referring to FIG. 2, the back electrode layer 200 is formed on the support substrate 100. The back electrode layer 200 is patterned to form the first through holes TH1. Accordingly, a plurality of back electrodes are formed on the support substrate 100. The back electrode layer 200 is patterned by a laser.

The back electrode layer 200 may include a material such as Mo. The back electrode layer 200 may include at least two layers under process conditions different from each other.

The first through holes TH1 expose the top surface of the support substrate 100, and may have the width in the range of about 50 μm to about 900 μm.

In addition, an additional layer such as an anti-diffusion layer may be interposed between the support substrate 100 and the back electrode 200, and the first through holes TH1 expose the top surface of the additional layer.

Referring to FIG. 3, the light absorbing layer 300, the buffer layer 400, and the high resistance buffer layer 500 are formed on the back electrode layer 200.

The light absorbing layer 300 may be formed through a sputtering process or an evaporation scheme.

The light absorbing layer 300 is formed by extensively using schemes, such as a scheme of forming a Cu(In,Ga)Se2 (CIGS) based-light absorbing layer 300 by simultaneously or separately evaporating Cu, In, Ga, and Se and a scheme of performing a selenization process after a metallic precursor film has been formed.

Regarding the details of the selenization process after the formation of the metallic precursor layer, the metallic precursor layer is formed on the back contact electrode 200 through a sputtering process employing a Cu target, an In target, or a Ga target.

Thereafter, the metallic precursor layer is subject to the selenization process so that the Cu(In,Ga)Se2 (CIGS) based-light absorbing layer 300 is formed.

In addition, the sputtering process employing the Cu target, the In target, and the Ga target and the selenization process may be simultaneously performed.

In addition, a CIS or a CIG light absorbing layer 300 may be formed through a sputtering process employing only Cu and In targets or only Cu and Ga targets and the selenization process.

The buffer layer 400 is formed by depositing cadmium sulfide (CdS) through a sputtering process and a Chemical Bath Deposition (CBD).

Thereafter, the high resistance buffer layer 500 is formed by depositing zinc oxide on the buffer layer 400 through the sputtering process.

The buffer layer 400 and the high resistance buffer layer 500 are deposited at a low thickness. For example, the thicknesses of the buffer layer 400 and the high resistance buffer layer 500 may be in the range of about 1 nm to about 80 nm.

Referring to FIG. 4, the second through holes TH2 are formed by removing portions of the light absorbing layer 300, the buffer layer 400, and the high resistance buffer layer 500.

The second through holes TH2 may be formed by a mechanical device such as a tip or a laser device.

In detail, the light absorbing layer 300, the buffer layer 400, and the high-resistance buffer layer 500 may be patterned by the mechanical device such as a tip. The tip may be in the range of about 5 μm to about 900 μm.

In this case, the light absorbing layer 300, the buffer layer 400, and the high resistance buffer layer 500 may be patterned in a direction inclined with respect to the support substrate 100. The end of the tip may extend in a direction inclined with respect to the support substrate 100. The light absorbing layer 300, the buffer layer 400, and the high resistance buffer layer 500 are pressurized and patterned in a direction inclined with respect to the support substrate 100 or the back electrode layer 200.

In addition, the second through hole TH2 may be patterned by a laser. In this case, the laser may be irradiated to the light absorbing layer 300, the buffer layer 400, and the high resistance buffer layer 500 in a direction inclined with respect to the support substrate 100.

Accordingly, the light absorbing layer 300, the buffer layer 400, and the high resistance buffer layer 500 may be formed in a direction inclined with respect to the support substrate 100.

In addition, the second through holes TH2 may be formed by the laser having one-sided energy density. In other words, the energy density of the laser is more highly represented at a position close to the second inner lateral side 302.

Even if the laser having one-sided energy density is irradiated to the light absorbing layer 300 perpendicularly to the support substrate 100 as described above, the second through holes TH2 having the inner lateral side formed in the overhang structure may be formed in the light absorbing layer 300.

Referring to FIG. 5, the front electrode layer 600 is formed on the light absorbing layer 300 and in the second through holes TH2. In other words, the front electrode layer 600 may be formed by depositing a transparent conductive material on the high resistance buffer layer 500 and in the second through hole TH2.

For example, the front electrode layer 600 may be formed by depositing a transparent conductive material such as AZO on the top surface of the high resistance buffer layer 500 and in the second through holes TH2 through the sputtering process.

The transparent conductive material may be deposited perpendicularly to the support substrate 100.

In this case, the connection part may be formed by depositing the transparent conductive material in the second through hole TH2.

Since the second through holes TH2 include the first inner lateral side 301 having the overhang structure, the front electrode layer 600 are naturally patterned. In other words, the transparent conductive material is not deposited in the recess part R, but the disconnection region CT may be formed.

As described above, the solar cell panel having the improved photoelectric conversion efficiency can be easily fabricated.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell apparatus comprising:
a support substrate;
a back electrode layer on the support substrate;
a light absorbing layer on the back electrode layer;
a buffer layer on the light absorbing layer;
a front electrode layer on the buffer layer;
a first through hole in the back electrode layer to expose a top surface of the support substrate; and
a second through hole formed through the light absorbing layer and the buffer layer,
wherein the second through hole is overlapped with a portion of the first through hole.

2. The solar cell apparatus of claim 1, wherein a portion of the second through hole is provided in the first through hole.

3. The solar cell apparatus of claim 1, wherein the second through hole comprises a first part to expose the top surface of the support substrate and a second part to expose a top surface of the back electrode layer.

4. The solar cell apparatus of claim 3, wherein the first part is overlapped with the portion of the first through hole.

5. The solar cell apparatus of claim 1, wherein the front electrode layer is provided in a portion of the second through hole.

6. The solar cell apparatus of claim 3, wherein a first inner lateral side of the second through hole is inclined in an overhang structure with respect to the top surface of the support substrate.

7. The solar cell apparatus of claim 6, wherein the second through hole comprises a second inner lateral side facing the first inner lateral side, and the second inner lateral side is inclined in the overhang structure with respect to the top surface of the back electrode layer.

8. The solar cell apparatus of claim 7, wherein an angle between the second inner lateral side and the top surface of the back electrode layer, which is provided inward of the second through hole, is in a range of 30° to 60°.

9. The solar cell apparatus of claim 7, wherein the front electrode layer covers the first inner lateral side and a bottom surface of the first part.

10. The solar cell apparatus of claim 7, wherein the front electrode layer comprises a disconnection region to expose a portion or an entire portion of the second inner lateral side.

11. (canceled)

12. (canceled)

13. (canceled)

14. (canceled)

15. (canceled)

16. (canceled)

17. The solar cell apparatus of claim 1, wherein a transparent connection part is provided in the first through holes.

18. The solar cell apparatus of claim 17, wherein the first through hole has a width in the range of 50 μm to 900 μm.

19. The solar cell apparatus of claim 1, wherein the second through hole has a width in the range of 5 μm to 800 μm.

20. The solar cell apparatus of claim 8, wherein the second through hole forms a protrusion and recess.

21. The solar cell apparatus of claim 20, wherein the protrusion protrudes inward of the second through hole, and the recess is formed under the protrusion.
